(19) United States
(12) Patent Application Publication
(10) Pub. No.: US 2009/0085589 A1
(43) Pub. Date: Apr. 2, 2009

(54) WAFER LEVEL TESTING METHOD FOR RFID TAGS

(76) Inventors: PINGFU HSIEH, (US); Juili Sun, (US); Mingkun Chen, Kaohsiung (TW)

Correspondence Address: BEEDAR TECHNOLOGY INC., R206, #12, NAN-KE 2ND ROAD,, TAINAN SCIENCE-BASED INDUSTRIAL PARK, TAINAN, TW

(21) Appl. No.: 11/865,076

(22) Filed: Oct. 1, 2007

(51) Int. Cl. G01R 31/303

(52) U.S. Cl. 324/750

(57) ABSTRACT

A wafer level testing method for RFID tags is disclosed. The method comprises: providing a semiconductor wafer having a plurality of RFID tag chips, wherein each of the RFID tag chips includes at least one detachable inductance and an embedded capacitance to form a resonant circuit; exposing the RFID tag chips to microwave energy, wherein the RFID tag chips send a plurality of wireless signals after a wireless power conversion; receiving the wireless signals and calculating a power level thereof; and comparing the power level to a predetermined power level to obtain the wafer yield.

### FIELD OF THE INVENTION

This invention relates to a wafer level testing method, and more particularly, to a wafer level testing method for a plurality of RFID tag chips.

### BACKGROUND OF THE INVENTION

Radio Frequency IDentification (RFID) tags are semiconductor chips that can positively respond to a wireless signal that inquires into the RFID tag's existence. RFID tags are expected to be applied at least to automated inventory management and distribution systems. As an example, after affixing an RFID tag to a pallet, the pallet can wirelessly identify itself so that the package whereabouts can be tracked or the logistical transportation managed in an automated fashion.

RFID tags are sensitive to costs of production. Here, the less expensive an RFID tag, the easier it is to justify the expense of distributing RFID tags amongst goods that are warehoused and/or transported. RFID tags, being semiconductor chips, are manufactured on wafers each containing many discrete RFID tag chips. If the RFID tag chips from a same wafer are not functionally tested for the first time until after they have been diced from the wafer and individually packaged, the expense of packaging the portion of chips that ultimately fail their functional test is pure economic waste. Therefore it is financially sensible for the RFID tag manufacturer to eliminate this waste through “on wafer” functional testing.

On wafer functional testing is the functional testing of semiconductor chips that have not yet been diced into individual chips from their corresponding wafer. FIG. 1A shows a traditional wafer 100 that has been organized into multiple identical patterns, each consisting of geometric data present on a mask set, or “reticle”. (Though the term “reticle” literally applies to the tooling used to pattern the wafer, herein we shall use the term to signify the portion of a wafer uniquely fabricated from this pattern, for expediency.) A single reticle 101 has been shaded in FIG. 1A. Each reticle typically contains multiple semiconductor chips (often identically designed). Breaking down the design of the wafer as a whole into an array of reticles allows for “step-and-repeat” processes that are applied to the wafer during the manufacture of its semiconductor chips (e.g., photolithography).

Referring to FIG. 1B, when the chips on the semiconductor wafer 100 are ready to be tested, a tester 103 applies and receives test signals through a wafer test probe 102. A wafer test probe 102 is a special fixture that is designed to land on specific “landing pads” that have been manufactured on the wafer 100 for the purpose of receiving and/or sending test signals from/to the tester 103 to/from the wafer 100. Based on the results observed by the tester 103 in response to the signals applied by the tester 103, the tester identifies defective chips. The defective chips are identified as scrap, and, as a consequence, any packaging and further testing costs associated with their production is avoided.

However, the wafer test probe 102 has to land on each chip on the semiconductor wafer 100 for testing. When the dimension of the semiconductor chip on the semiconductor wafer 100 is reduced, i.e. the quantity of the semiconductor chip thereon is increased, difficulties and time of the wafer test probe 102 for testing are also raised. Further, the wafer test probe 102 is expensive. When the dimension or position of the semiconductor chip on the semiconductor wafer 100 is changed, the wafer test probe 102 has to be redesigned for testing.

### SUMMARY OF THE INVENTION

Therefore, an aspect of the present invention is to provide a wafer level testing method for RFID tags to test a plurality of RFID tag chips on a semiconductor wafer without contact being made, thereby enhancing test speed and efficiency.

Another aspect of the present invention is to provide a semiconductor wafer for RFID tags testing, so that a plurality of RFID tag chips can be tested in a single testing process, and test efficiency is enhanced.

Another aspect of the present invention is to provide a wafer level testing method, wherein each of the RFID tag chips on the wafer includes a built-in self test (BIST) circuit to perform a built-in self testing step.

According to an embodiment of the present invention, the semiconductor wafer testing method comprises: providing a semiconductor wafer having a plurality of RFID tag chips, wherein each of the RFID tag chips includes at least one detachable inductance and an embedded capacitance to form a resonant circuit; exposing the RFID tag chips to microwave energy, wherein the resonant circuit of each of the RFID tag chips receives microwave energy to perform a wireless power conversion, and the RFID tag chips send a plurality of wireless signals after the wireless power conversion; receiving the wireless signals and calculating a power level of the wireless signals; and comparing the power level to a predetermined power level to obtain a wafer yield of the semiconductor wafer.

According to another embodiment of the present invention, the semiconductor wafer for wafer level testing comprises a plurality RFID tag chips, wherein each of the RFID tag chips includes at least one detachable inductance and an embedded capacitance to form a resonant circuit, and the resonant circuit of each of the RFID tag chips receives microwave energy to perform a wireless power conversion, and the RFID tag chips send a plurality of wireless signals after the wireless power conversion.

Therefore, with the application of the wafer level testing method for the RFID tag chips disclosed in the embodiments of the present invention, the RFID tag chips are simultaneously tested without making contact, thereby enhancing test speed and efficiency. Further, the way of testing the RFID tag chips is simple, contactless and low-priced, and conventional test probe can be prevented when testing.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows a semiconductor wafer;

FIG. 1B shows a wafer tester and corresponding test probe involved in the test of a wafer;

FIG. 2 shows a semiconductor wafer placed in the detection apparatus for testing according to a first embodiment of the present invention;

FIG. 3 is a flow diagram showing the wafer level testing method according to a first embodiment of the present invention;

FIG. 4 shows a semiconductor wafer according to a first embodiment of the present invention;

FIG. 5A and FIG. 5C show partly top views of a semiconductor wafer according to a first embodiment of the present invention;

FIG. 5B shows a partly cross-sectional view according to FIG. 5A;

FIG. 5D shows a partly cross-sectional view according to FIG. 5C;

FIG. 6A shows a top view of a RFID tag chip according to a first embodiment of the present invention;

FIG. 6B shows a cross-sectional view according to FIG. 6A;

FIG. 7 is a circuit diagram showing a RFID tag circuit and a detection element according to a first embodiment of the present invention;

FIG. 8 is a graph showing a power level compared with a predetermined power level t according to a first embodiment of the present invention;

FIG. 9 is a graph showing the amplitude level accumulated from the wireless signals according to a first embodiment of the present invention;

FIG. 10 is a graph showing wireless signals in different time slots according to a first embodiment of the present invention;

FIG. 11A shows a partly top view of a semiconductor wafer according to a second embodiment of the present invention; and

FIG. 11B and FIG. 11C show partly cross-sectional views of a RFID tag according to a second embodiment of the present invention.

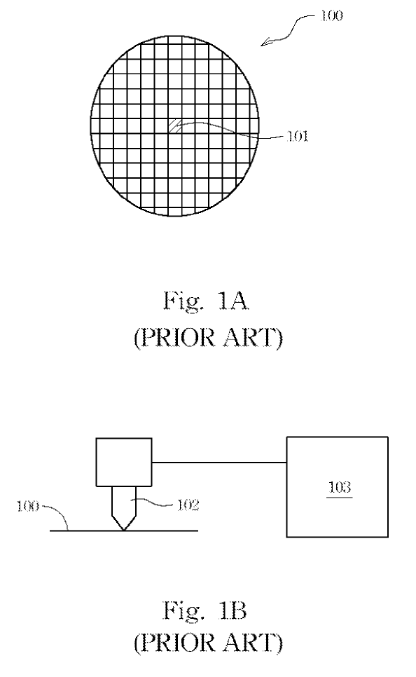

### DETAILED DESCRIPTION OF THE PREFERRED EMBODIMENT

In order to make the illustration of the present invention more explicit and complete, the following description is stated with reference to FIG. 3 through FIG. 11.

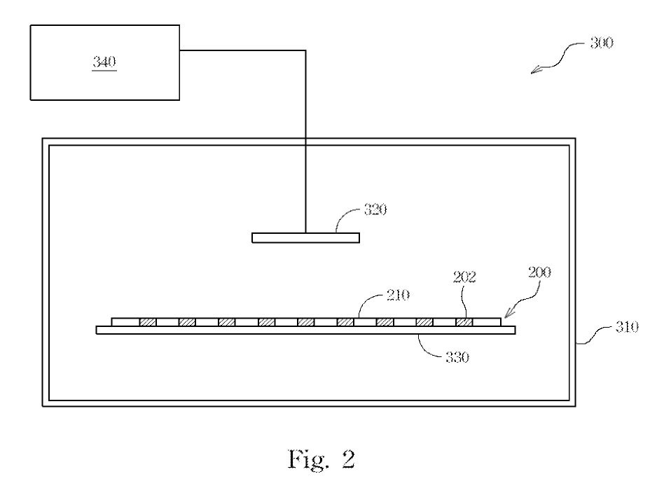

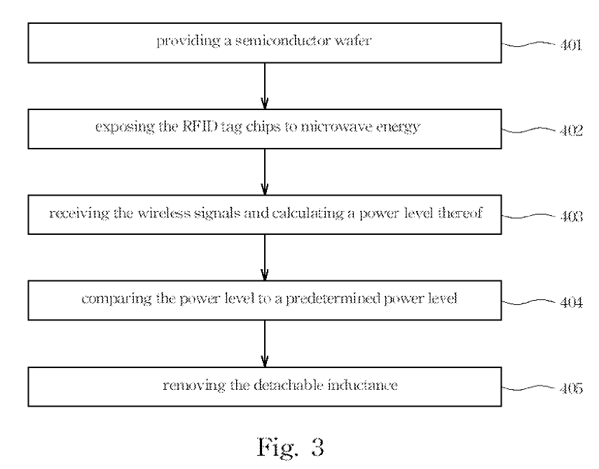

Refer to FIG. 2 and FIG. 3. FIG. 2 shows a semiconductor wafer placed in the detection apparatus for testing according to a first embodiment of the present invention. FIG. 3 is a flow diagram showing the wafer level testing method according to a first embodiment of the present invention. The wafer level testing method comprises: providing a semiconductor wafer 200 having a plurality of RFID tag chips 210, wherein each of the RFID tag chips 210 includes at least one detachable inductance 211 and an embedded capacitance 211 to form a resonant circuit 201, and the semiconductor wafer 200 may be a silicon substrate wafer; exposing the RFID tag chips 210 to microwave energy (i.e., the frequency of microwave energy is substantially between 0.3 GHz and 300 GHz) (step 402), wherein each of the RFID tag chips 210 receives microwave energy to perform a wireless power conversion, and the RFID tag chips 210 send a plurality of wireless signals after the wireless power conversion; receiving the wireless signals and calculating a power level thereof (step 403); comparing the power level to a predetermined power level to obtain the wafer yield of the semiconductor wafer 200 (step 404); and removing the detachable inductance 211 after obtaining the wafer yield (step 405). Further, when testing the semiconductor wafer 200, a detection apparatus 300 is provided to test the semiconductor wafer 200. Therefore, the semiconductor wafer 200 with the RFID tag chips 210 can be tested by the non-contacting test method of the present embodiment to measure the wafer yield thereof in a single test process, thereby largely reducing testing time and effort.

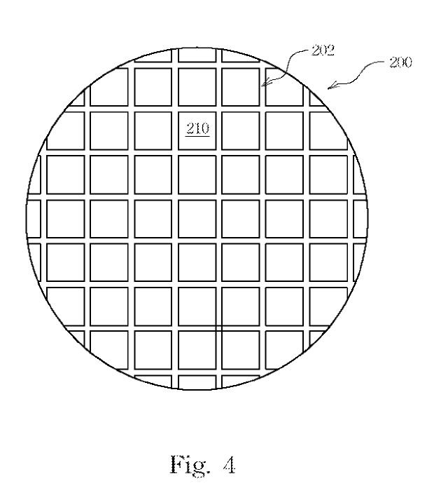

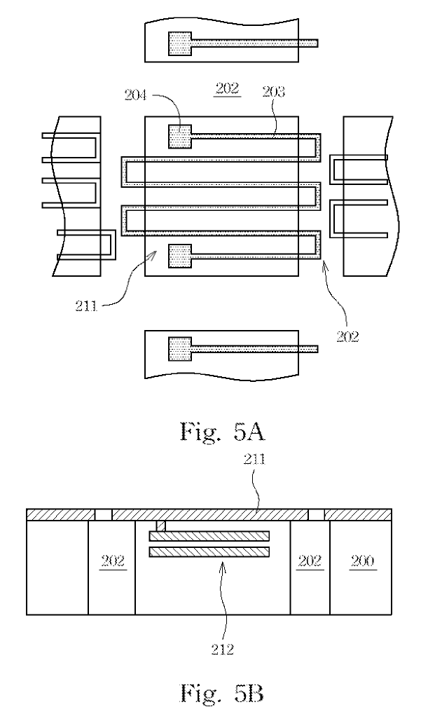

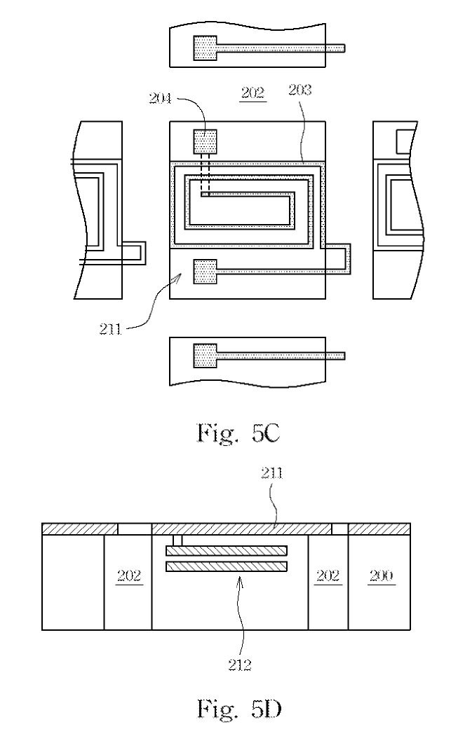

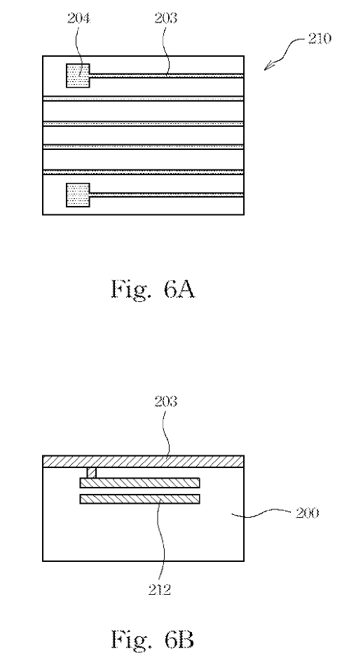

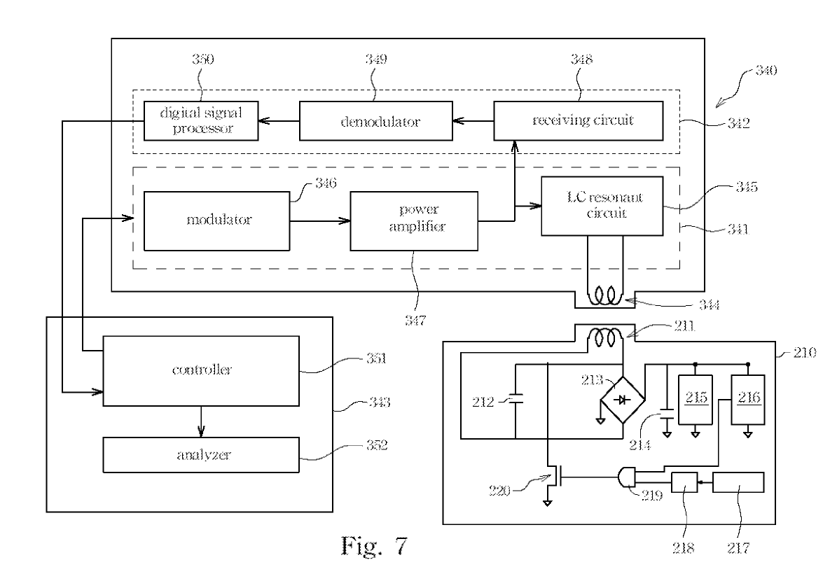

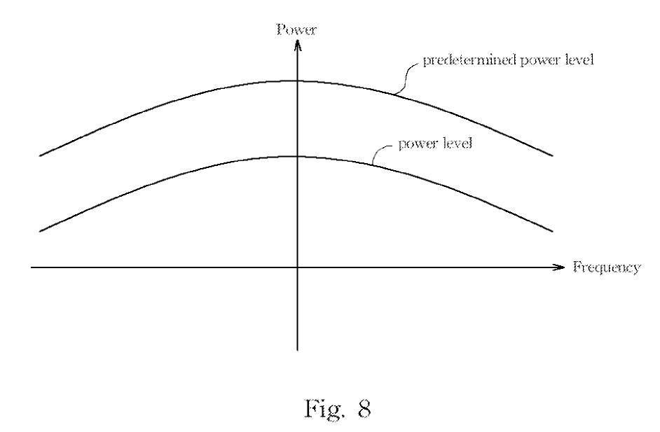

Refer to FIG. 4 through FIG. 7. FIG. 4 shows a semiconductor wafer according to a first embodiment of the present invention. FIG. 5A and FIG. 5C show partly top views of a semiconductor wafer according to a first embodiment of the present invention. FIG. 5B shows a partly cross-sectional view according to FIG. 5A. FIG. 5D shows a partly cross-sectional view according to FIG. 5C. FIG. 6A shows a top view of a RFID tag chip according to a first embodiment of the present invention. FIG. 6B shows a cross-sectional view according to FIG. 6A. FIG. 7 is a circuit diagram showing a RFID tag circuit and a detection element according to a first embodiment of the present invention. When performing the wafer level testing for the RFID tag chips 210 (i.e. testing the semiconductor wafer 200 with the RFID tag chips 210), first, the semiconductor wafer 200 is provided (step 401), and the detection apparatus 300 is provided to measure the wafer yield thereof. The semiconductor wafer 200 can be divided into the RFID tag chips 210 with a plurality of saw streets 202. Preferably, the area of each of the RFID tag chips is substantially less than 2.25 mm². Each of the RFID tag chips 210 may further include at least one detachable inductance 211, an embedded capacitance 212, a rectifier 213, a storage capacitance 214, a controller 215, a memory 216, a random number generator 217, a counter 218, an emitting control circuit 219 and a modulator 220. The detachable inductance 211 and the embedded capacitance 212 form a resonant circuit 201. In the present embodiment, the resonant circuit 201 can be a dummy antenna formed on each of the RFID tag chips 210 for testing before the semiconductor wafer 200 is divided into the RFID tag chips 210, wherein the detachable inductance 211 can be removed after the obtaining the wafer yield to remove the resonant circuit 201. The detachable inductance 211 is formed on the surface of each of the RFID tag chips 210, wherein the detachable inductance 211 has a coil 203 and at least one I/O pad 204. The I/O pad 204 is connected between the coil 203 and the embedded capacitance 212, thereby electrically connecting the detachable inductance 211 and the embedded capacitance 212. The coil 203 of the detachable inductance 211 may be worm-shaped (as shown in FIG. 5A), whirlpool-shaped (as shown in FIG. 5C) or any other coil structure for being an inductance. In the present embodiment, at least a portion of the coil 203 is located in the saw streets 202. Therefore, when the semiconductor wafer 200 is divided with the saw streets 202, at least a portion of the coil 203 is disconnected, and the detachable inductance 211 can be removed after obtaining the wafer yield. The detachable inductance 211 may be made of metal material (such as Cu, Al, Au, Cr, Ti, Mo, Tl, W or any combination thereof) or polycrystalline silicon material. The embedded capacitance 212 is embedded in each of the RFID tag chips 210 and electrically connected to the detachable inductance 211 to form the resonant circuit 201. The rectifier 213 processes the microwave energy received from the resonant circuit 201 to convert a DC power supply voltage, thereby forming the wireless power conversion. The rectifier 213 may be a full bridge circuit, a half bridge circuit, a transistor, a diode or any combination thereof. The DC power supply voltage (VDD) is fed to the storage capacitance 214 to provide power supply to the other RFID tag circuits (such as the controller 215, the memory 216, the random number generator 217, the counter 218, the emitting control circuit 219 and the modulator 220). After the wireless power conversion, the emitting control circuit 219 controls the resonant circuit 201 to send the wireless signals.

It is worth mentioning that the RFID tag circuit of the embodiment is merely one example of the present invention. However, the present invention does not limit the RFID tag circuit, and a person skilled in the art can use different kinds of circuit structure to achieve the same technical effect as the present invention.

Refer to FIG. 2 and FIG. 7 again. The detection apparatus 300 of the present embodiment may comprise a test chamber 310, a detector 320, a movable stage 330 and a detection element 340. The detector 320 and the movable stage 330 are disposed in the test chamber 310 to isolate external noise when testing, wherein the test chamber 310 is preferably made of metal material for noise isolating. Further, the semiconductor wafer 200 can be heated or cooled in the test chamber 310, thereby testing the semiconductor wafer 200 in high temperature testing conditions or a low temperature testing conditions. The detector 320 is disposed according to the position of the semiconductor wafer 200 to emit microwave energy to the semiconductor wafer 200 and to receive the wireless signals therefrom. The semiconductor wafer 200 is placed on the movable stage 330 for testing, and the movable stage 330 is movable corresponding to the detector 320 when testing. The movable stage 330 is preferably made of glass, ceramics or other nonmetallic material, and may have a vacuum chuck or an electrostatic chuck to hold the semiconductor wafer 200. The detection element 340 is electrically connected to the detector 320, wherein the detection element 340 may be disposed in or outside the test chamber 310. The detection element 340 includes a transmitter 341, a receiver 342 and a test controller 343. The transmitter 341 transmits microwave energy to the detector 320 for emitting, wherein the transmitter 341 may include at least one microwave coil 344, a LC resonant circuit 345, a modulator 346 and a power amplifier 347 for modulating the microwave signal and transmitting microwave energy with the microwave coil 344. The receiver 342 receives the wireless signals from the semiconductor wafer 200 and sends the wireless signals to the test controller 343 for analyzing, wherein the receiver 342 may include a receiving circuit 348, a demodulator 349 and a digital signal processor 350 for demodulating and processing the wireless signals. The test controller 343 is electrically connected to the transmitter 341 and the receiver 342, and the test controller 343 controls the transmitter 341 to transmit microwave energy and analyzes the wireless signals for obtaining the wafer yield of the semiconductor wafer 200, wherein the test controller 343 may include a controller 351 and an analyzer 352, thereby controlling the transmitter 341 and analyzing the wireless signals.

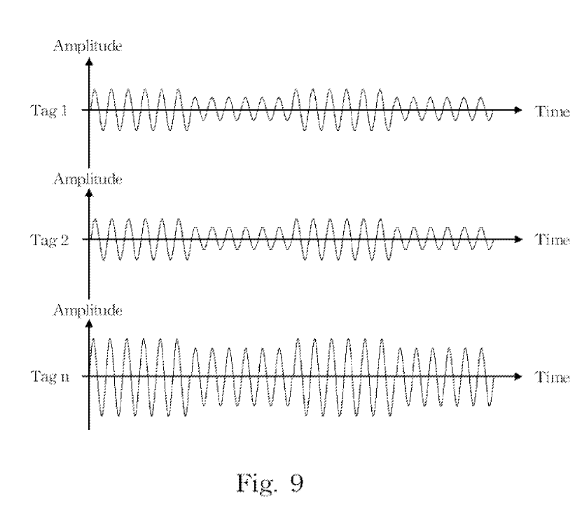

Refer to FIG. 2, FIG. 8 and FIG. 9. FIG. 8 is a graph showing a power level compared with a predetermined power level according to a first embodiment of the present invention. FIG. 9 is a graph showing the amplitude level accumulated from the wireless signals according to a first embodiment of the present invention. When the RFID tag chips 210 on the semiconductor wafer 200 are exposed to microwave energy emitted from the detection apparatus 300 (step 402), first, the semiconductor wafer 200 is placed and held on the movable stage 330 of the detection apparatus 300. Then, the detector 320 emits microwave energy to the semiconductor wafer 200. When the RFID tag chips 210 receive microwave energy, wireless power conversion occurs in each of the RFID tag chips 210. Normally, if one of the RFID tag chips 210 is not defective (i.e., a good die), the one thereof can transmit a wireless signal to the detection apparatus 300 after the wireless power conversion. Contrarily, if one of the RFID tag chips 210 is defective (i.e., a bad die) it may not transmit a wireless signal to the detection apparatus 300. Then, the wireless signals are received and calculated by the detection apparatus 300 (step 403). The wireless signals are received by the detector 320, and are further demodulated and processed by the receiver 342. The analyzer 352 of the test controller 343 calculates a power level according to the wireless signals received form the receiver 342. Then, the power level is compared with the predetermined power level (step 404), wherein the predetermined power level is determined according to 100 percentages wafer yield, thereby obtaining the wafer yield of the semiconductor wafer 200. For example, when the wireless signals from the RFID tag chips 210 (such as Tag 1 and Tag2) are calculated, the amplitude of the wireless signals are accumulated by the detection element 340, so that the amplitude level accumulated from the wireless signals can be regarded as the power level to compare with the predetermined power level. After obtaining the wafer yield, the detachable inductance 211 of each of the RFID tag chips is removed (step 405). In the present embodiment, the detachable inductance 211 may be removed by disposing at least portion of the coil 203 thereof located in the saw streets 202.

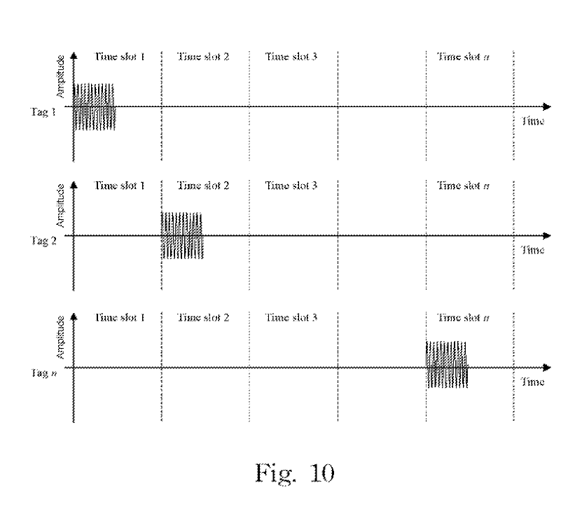

FIG. 10 is a graph showing wireless signals in different time slots according to a first embodiment of the present invention. When the RFID tag chips 210 transmit the wireless signals to the detection apparatus 300, the random number generator 217 and the counter 218 of each of the RFID tag chips 210 can form a plurality of time slots and make each of the RFID tag chips 210 transmit the wireless signal during different time slots (Time slot 1, Time slot 2 . . . Time slot n as shown in FIG. 10). Therefore, each of the RFID tag chips 210 is identified with the different time slots and analyzed by the analyzer 352 for testing, even if the numerous RFID tag chips 210 are tested simultaneously, and the defective one of the RFID tag chips 210 can be identified.

It is worth mentioning that the semiconductor wafer 200 of the present embodiment is divided into the RFID tag chips 210 after the wafer level testing, and the detachable inductance 211 is also removed.

Therefore, the wafer level testing method for the RFID tag chips of the present embodiment can test the RFID tag chips simultaneously without any contact, thereby enhancing test speed and efficiency. Further, the way of forming the detachable inductance and the embedded capacitance on each of the RFID tag chips is simple and low-priced, and conventional test probe is prevented. Therefore, the wafer level testing method is largely low-priced and simple.

It should be appreciated that although the present description refers to a RFID tag, at least some of the techniques for implementing on wafer testing may be applied to semiconductor die targeted for other applications (i.e., non RFID tag die).

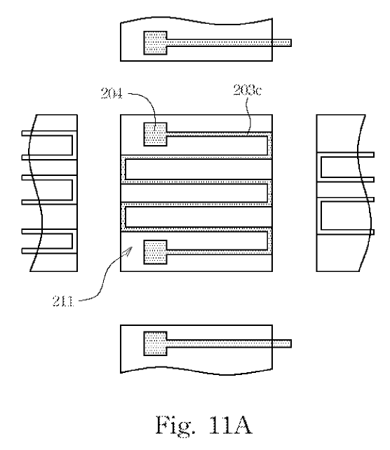

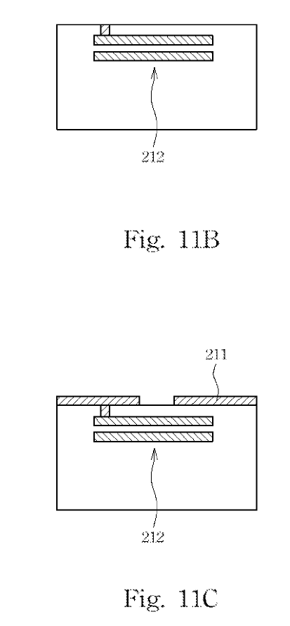

Refer to FIG. 11A through FIG. 11C. FIG. 11A shows a partly top view of a semiconductor wafer according to a second embodiment of the present invention. FIG. 11B and FIG. 11C show partly cross-sectional views of a RFID tag according to a second embodiment of the present invention. Some reference numerals shown in the first embodiment are used in the second embodiment of the present invention. The construction shown in the second embodiment is similar to that in the first embodiment with respect to configuration and function, and thus is not stated in detail herein.

Refer to FIG. 11A through FIG. 11C, in comparison with the first embodiment, the coil 203a of the detachable inductance 211 of the second embodiment may have no any portion located in the saw streets 202. At this time, at least a portion of the coil 203a is etched (such as using dry etching or wet etching) after the wafer level testing, thereby removing the detachable inductance 211. Therefore, the detachable inductance 211 can be also removed after testing.

Therefore, the wafer level testing method for the RFID tag chips shown in the respective embodiments of the present invention can test the RFID tag chips simultaneously without contacting, thereby enhancing test speed and efficiency. Further, the testing method for the RFID tag chips is largely low-priced and simple.

As is understood by a person skilled in the art, the foregoing embodiments of the present invention are strengths of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A semiconductor wafer testing method, comprising:
providing a semiconductor wafer having a plurality of RFID tag chips, wherein each of the RFID tag chips includes at least one detachable inductance and an embedded capacitance to form a resonant circuit;
exposing the RFID tag chips to microwave energy, wherein the resonant circuit of each of the RFID tag chips receives microwave energy to perform a wireless power conversion, and the RFID tag chips send a plurality of wireless signals after the wireless power conversion;
receiving the wireless signals and calculating a power level of the wireless signals; and
comparing the power level to a predetermined power level to obtain a wafer yield of the semiconductor wafer.

2. The method as claimed in claim 1, further comprising;
removing the detachable inductance after obtaining the wafer yield.

3. The method as claimed in claim 2, wherein the semiconductor wafer is divided into the RFID tag chips with a plurality of saw streets, and at least a portion of a coil of the detachable inductance is located in the saw streets so that the detachable inductance is removed when the semiconductor wafer is divided into the RFID tag chips.

4. The method as claimed in claim 2, wherein at least a portion of a coil of the detachable inductance is etched to remove the detachable inductance after obtaining the wafer yield.

5. The method as claimed in claim 1, further comprising;
providing a detection apparatus to measure the wafer yield of the semiconductor wafer.

6. The method as claimed in claim 5, wherein the detection apparatus comprises a test chamber, and the semiconductor is tested in the test chamber to isolate external noise.

7. The method as claimed in claim 6, wherein the test chamber is made of metal material.

8. The method as claimed in claim 5, wherein the detection apparatus comprises a movable stage, and the semiconductor wafer is placed on the movable stage for testing.

9. The method as claimed in claim 8, wherein the movable stage is made of nonmetallic material.

10. The method as claimed in claim 9, wherein the movable stage is made of glass or ceramics.

11. The method as claimed in claim 5, wherein the detection apparatus comprises:
a detector disposed according to the position of the semiconductor wafer to emit microwave energy and to receive the wireless signals therefrom; and
a detection element electrically connected to the detector, wherein the detection element comprises:
a transmitter to transmit microwave energy to the detector;
a receiver to receive the wireless signals from the semiconductor wafer; and
a test controller electrically connected to the transmitter and the receiver, wherein the test controller controls the transmitter to transmit microwave energy and analyzes the wireless signals for obtaining the wafer yield of the semiconductor wafer.

12. The method as claimed in claim 1, wherein the amplitude of the wireless signals is accumulated to calculate the power level.

13. The method as claimed in claim 1, where each of the RFID tag chips transmits the wireless signal during different time slots so that each of the RFID tag chips is identified with the different time slots.

14. The method as claimed in claim 1, wherein the frequency of microwave energy is substantially between 0.3 GHz and 300 GHz.

15. The method as claimed in claim 1, further comprises:
heating the semiconductor wafer for high temperature testing conditions.

16. The method as claimed in claim 1, further comprises:
cooling the semiconductor wafer for low temperature testing conditions.

17. A semiconductor wafer for wafer level testing, comprising:
a plurality RFID tag chips, wherein each of the RFID tag chips includes at least one detachable inductance and an embedded capacitance to form a resonant circuit, and the resonant circuit of each of the RFID tag chips receives microwave energy to perform a wireless power conversion, and the RFID tag chips send a plurality of wireless signals after the wireless power conversion.

18. The semiconductor wafer as claimed in claim 17, further comprising;
a plurality of saw streets formed between the RFID tag chips, wherein at least a portion of a coil of the detachable inductance is located in the saw streets.

19. The method as claimed in claim 17, wherein each of the RFID tag chips further includes a random number generator and the counter to form a plurality of time slots and allow each of the RFID tag chips to transmit the wireless signal during the different time slots.

20. The method as claimed in claim 17, wherein the material of the detachable inductance is selected from a group of Cu, Al, Au, Cr, Ti, Mo, Tl, W and any combination thereof.

21. The method as claimed in claim 17, wherein the detachable inductance is made of polycrystalline silicon.

22. A semiconductor wafer testing method, comprising:
providing a semiconductor wafer having a plurality of RFID tag chips, wherein each of the RFID tag chips includes at least one detachable inductance and an embedded capacitance to form a resonant circuit;
exposing the RFID tag chips to microwave energy by using a detection apparatus, wherein the resonant circuit of each of the RFID tag chips receives microwave energy to perform a wireless power conversion, and the RFID tag chips send a plurality of wireless signals after the wireless power conversion;
receiving the wireless signals and calculating a power level of the wireless signals by using the detection apparatus; and
comparing the power level to a predetermined power level by using the detection apparatus to obtain a wafer yield of the semiconductor wafer.

23. The method as claimed in claim 22, further comprising;
removing the detachable inductance after obtaining the wafer yield.

24. The method as claimed in claim 23, wherein the semiconductor wafer is divided into the RFID tag chips with a plurality of saw streets, and at least a portion of a coil of the detachable inductance is located in the saw streets so that the detachable inductance is removed when the semiconductor wafer is divided into the RFID tag chips.

25. The method as claimed in claim 23, wherein at least a portion of a coil of the detachable inductance is etched to remove the detachable inductance after obtaining the wafer yield.

26. The method as claimed in claim 22, wherein the detection apparatus comprises a test chamber, and the semiconductor is tested in the test chamber to isolate external noise.

27. The method as claimed in claim 26, wherein the test chamber is made of metal material.

28. The method as claimed in claim 22, wherein the detection apparatus comprises a movable stage, and the semiconductor wafer is placed on the movable stage for testing.

29. The method as claimed in claim 28, wherein the movable stage is made of nonmetallic material.

30. The method as claimed in claim 29, wherein the movable stage is made of glass or ceramics.

31. The method as claimed in claim 22, wherein the detection apparatus comprises:
a detector disposed according to the position of the semiconductor wafer to emit microwave energy and to receive the wireless signals therefrom; and
a detection element electrically connected to the detector, wherein the detection element comprises:
a transmitter to transmit microwave energy to the detector;
a receiver to receive the wireless signals from the semiconductor wafer; and
a test controller electrically connected to the transmitter and the receiver, wherein the test controller controls the transmitter to transmit microwave energy and analyzes the wireless signals for obtaining the wafer yield of the semiconductor wafer.

32. The method as claimed in claim 22, wherein the amplitude of the wireless signals is accumulated to calculate the power level.

33. The method as claimed in claim 22, where each of the RFID tag chips transmits the wireless signal during different time slots so that each of the RFID tag chips is identified with the different time slots.

34. The method as claimed in claim 22, wherein the frequency of microwave energy is substantially between 0.3 GHz and 300 GHz.

35. The method as claimed in claim 22, further comprises:
heating the semiconductor wafer for high temperature testing conditions.

36. The method as claimed in claim 22, further comprises:
cooling the semiconductor wafer for low temperature testing conditions.

37. A semiconductor wafer testing method, comprising:
providing a semiconductor wafer having a plurality of RFID tag chips, wherein each of the RFID tag chips includes at least one detachable inductance and an embedded capacitance to form a resonant circuit;
providing a detection apparatus, wherein the detection apparatus comprises:
a test chamber to allow the semiconductor to be tested therein;
a movable stage disposed in the test chamber, wherein the semiconductor wafer is placed on the movable stage for testing;
a detector disposed in the test chamber to emit microwave energy; and
a detection element electrically connected to the detector;
exposing the RFID tag chips to microwave energy by using the detector, wherein the resonant circuit of each of the RFID tag chips receives microwave energy to perform a wireless power conversion, and the RFID tag chips send a plurality of wireless signals after the wireless power conversion;
receiving the wireless signals by using the detector and calculating a power level of the wireless signals by using the detection element; and
comparing the power level to a predetermined power level by using the detection element to obtain a wafer yield of the semiconductor wafer.

38. A semiconductor wafer testing method, comprising:
providing a semiconductor wafer having a plurality of RFID tag chips and a plurality of saw streets, wherein each of the RFID tag chips includes at least one detachable inductance and an embedded capacitance to form a resonant circuit, and at least a portion of a coil of the detachable inductance is located in the saw streets;
exposing the RFID tag chips to microwave energy, wherein the resonant circuit of each of the RFID tag chips receives microwave energy to perform a wireless power conversion, and the RFID tag chips send a plurality of wireless signals after the wireless power conversion;
receiving the wireless signals and calculating a power level of the wireless signals;
comparing the power level to a predetermined power level to obtain a wafer yield of the semiconductor wafer; and
removing the detachable inductance by dicing the semiconductor wafer with the plurality of saw streets.
